(19) United States
(12) Patent Application Publication
(10) Pub. No.: US 2010/0069192 A1
(43) Pub. Date: Mar. 18, 2010

(54) POWER TRANSMISSION UNIT AND METHOD FOR ASSEMBLING SAME

(75) Inventor: Atsushi TABATA, Okazaki-shi (JP)

Correspondence Address: OBLON, SPIVAK, MCCLELLAND MAIER & NEUSTADT, L.L.P., 1940 DUKE STREET, ALEXANDRIA, VA, 22314, US

(73) Assignees: TOYOTA JIDOSHA KABUSHIKI KAISHA, Aichi (JP); AISIN AW CO., LTD., Anjyo-shi (JP)

(21) Appl. No.: 12/294,142

(22) PCT Filed: Mar. 22, 2007
(86) PCT No.: PCT/JP2007/055820

§ 371 Date: Sep. 23, 2009

(30) Foreign Application Priority Data
Mar. 23, 2006 (JP) 2006-081552

(51) Int. Cl. F16H 3/72; F16H 57/02; H05K 13/00

(52) U.S. Cl. 475/5; 74/606 R; 29/592.1

(57) ABSTRACT

A power transmission unit including an electric motor with a rotor arranged on an inner circumference of a stator and concentrically with the stator, and a transmission mechanism for transmitting power. A portion of a predetermined constructional element of the transmission mechanism protrudes toward the stator or rotor side, and the protruding portion functions as a guide portion for inserting the rotor into the stator concentrically. Thereby, a convenience in assembling an electric motor to be arranged adjacent to a transmission mechanism of a power transmission unit in a casing is realized.

### TECHNICAL FIELD

This invention relates to a power transmission unit comprising a transmission mechanism and an electric motor increasing a torque inputted to the transmission mechanism and decreasing a torque outputted from the transmission mechanism, and to an assembling method thereof.

### BACKGROUND ART

In the prior art, a unit composed of a combination of an internal combustion engine with an electric motor, a unit using an electric motor as a prime mover and so on are known as a power unit of a vehicle. In order to control a drive torque and speeds of the internal combustion engine and the electric motor, a transmission is employed in a vehicle having the power unit of those kinds. One example is disclosed in Japanese Patent Laid-Open No. 2003-127681. The system disclosed in Japanese Patent Laid-Open No. 2003-127681 is a hybrid vehicle drive system in which an internal combustion engine is connected with a carrier of a planetary gear mechanism, and a first motor/generator is connected with a sun gear of the planetary gear mechanism. Also, a ring gear is connected with a member of an input side of a geared automatic transmission. A member of an output side of the automatic transmission is connected with a propeller shaft, and a second motor/generator is connected with the propeller shaft. Thus, according to the system taught by Japanese Patent Laid-Open No. 2003-127681, the planetary gear mechanism functions as a distribution mechanism distributing an engine power to the first motor/generator and to the output side. A torque is added or absorbed by a second motor/generator in the process of transmitting the power from the distribution mechanism to the automatic transmission.

Japanese Patent Laid-Open No. 2001-268853 discloses a structure in which a motor stator is arranged in a housing, an input shaft of a transmission is arranged coaxially with the motor stator, and the input shaft is inserted into a motor rotor facing to the motor stator.

Various kinds of methods and procedures for inserting a rotor into a stator have been proposed in the prior art. For example, Japanese Patent Laid-Open No. 2005-138670 discloses an assembling method of electric motor of electric power steering device. According to the method taught by Japanese Patent Laid-Open No. 2005-138670, an end portion of a housing of a speed reduction mechanism having a protruding unitary shaft is fixed with a cylindrical housing having a stator on its inner circumference, and then, a rotor is inserted into the housing from an opening end side and the unitary shaft is pressed into the rotor. Also, Japanese Patent Laid-Open No. 2005-117807 discloses a configuration to improve efficiency of an installation work of a rotor and a stator in an engine generator. Specifically, according to the configuration disclosed in Japanese Patent Laid-Open No. 2005-117807, a fly-wheel housing is provided with a guide member, and a stator to be fixed with the fly-wheel housing is provided with a guided part. Likewise, a fly-wheel is provided with a guide member, and a rotor to be fixed with the fly-wheel is provided with a guided portion. Moreover, Japanese Patent Laid-Open No. 2002-165420 discloses a structure to insert a rotor into an inner circumference of a stator using a guide pin.

In the above-explained conventional electric motor and motor generator, a rotor having a permanent magnet is used. In case of inserting the above-explained rotor into an inner circumference of a stator, a magnetic force acts between the rotor and the stator. Therefore, it is difficult to keep those rotor and stator coaxially. As taught by Japanese Patent Laid-Opens Nos. 2001-268853 and 2005-138670, if the shaft arranged along a center axis of the stator is inserted directly into the rotor, adhesion of the rotor and the stator can be avoided. However, if a member or portion on which the rotor is mounted does not extend all along the center axis in the inner circumferential side of the stator, it is necessary to overwhelm the magnetic force to isolate the rotor from the stator. Alternatively, if the guide member or guide pin is provided as taught by Japanese Patent Laid-Opens Nos. 2005-117807 and 2002-165420, the rotor can be kept coaxially with the stator. However, such guide member or guide pin to be used only for assembling work has to be provided. That is, a number of constructional elements is increased. This means that steps of installing and uninstalling of such elements may be increased. In addition, it is necessary to ensure a space for the guide member or guide pin. Therefore, the constitution taught by Japanese Patent Laid-Opens Nos. 2005-117807 and 2002-165420 cannot be applied to an apparatus which does not have enough space for the guide member or guide pin.

### DISCLOSURE OF THE INVENTION

The present invention has been conceived noting the technical problems thus far described, and its object is to improve convenience in assembling a rotor in a power transmission unit comprising an electric motor and a transmission.

In order to achieve the above-mentioned object, according to the present invention, there is provided a power transmission unit comprising an electric motor having a rotor arranged in an inner circumference of a stator and concentrically with the stator, and a transmission mechanism for transmitting power, characterized in that a portion of a predetermined constructional element of the transmission mechanism protrudes toward the stator or rotor side, and the protruding portion functions as a guide portion for inserting the rotor into the stator concentrically.

According to the power transmission unit of the invention, the electric motor and the transmission mechanism are housed in a casing, a bulkhead integral with the casing is disposed between the electric motor and the transmission mechanism, the transmission mechanism is housed in a chamber defined by the bulkhead, and the electric motor is disposed adjacent to the bulkhead in a chamber opposite to the chamber housing the transmission mechanism.

The protruding portion functioning as the guide portion protrudes toward the electric motor side while penetrating the bulkhead, and supported by the bulkhead.

According to the power transmission unit of the invention, a portion of the protruding portion closer to the transmission side than a leading end side thereof functions as the guide portion.

In addition to above, the protruding portion functioning as the guide portion includes a shaft for transmitting a power to the transmission mechanism. The shaft is inserted into the rotor and allowed to rotate relatively therewith, and a connection member is interposed between the shaft and the rotor to connect the shaft and the rotor in a power transmittable manner.

According to the power transmission unit of the invention, the bulkhead interlocks with the casing at a spigot joint portion.

According to the power transmission unit of the invention, a hydraulic control unit is provided underneath the transmission mechanism.

Also, an oil pan is provided underneath the electric motor and the transmission mechanism to reserve oil used commonly in the electric motor and the transmission mechanism.

According to the power transmission unit of the invention, the rotor is held in a rotatable manner by the casing housing the electric motor and the transmission mechanism or by a member integral with the casing.

According to the power transmission unit of the invention, the casing or the member integral with the casing includes the bulkhead and an another bulkhead opposed to the bulkhead.

In addition to above, there is formed an oil passage passing through at least one of the bulkhead or another bulkhead.

In the power transmission unit of the invention, an electrical drive unit functioning as an electric motor or a generator and an internal combustion engine are connected with a differential mechanism, and the power transmission unit further comprises an electrical transmission varying a speed of the internal combustion engine continuously in accordance with a speed of the electrical drive unit.

According to the power transmission unit of the invention, the differential mechanism comprises a planetary gear mechanism.

In addition to above, the differential mechanism functions as a speed increasing mechanism the output speed thereof is higher than the speed of the internal combustion engine.

According to the power transmission unit of the invention, a portion of an output member of the differential mechanism or a member integral with the output member is connected with the shaft and the rotor.

More specifically, the portion of the output member or the member integral with the output member is splined to at least any of the shaft and the rotor.

According to the power transmission unit of the invention, the transmission mechanism includes a mechanical transmission changing a speed change ratio thereof by changing a power transmission route by a mechanical means.

More specifically, the mechanical transmission includes a planetary gear mechanism.

In addition, the mechanical transmission includes a mechanism setting a reverse stage.

According to another aspect of the invention, there is provided an assembling method of a power transmission unit, in which an electric motor having a rotor arranged in an inner circumference of a stator and concentrically with the stator and a transmission mechanism transmitting a power are housed in a casing, characterized by comprising: assembling the transmission mechanism by inserting elements of the transmission mechanism into the casing from one of the open ends of the casing to assemble those elements; thereafter fixing a bulkhead in the casing to define a chamber for housing the transmission mechanism; inserting an input shaft of the transmission mechanism into the bulkhead and holding the input shaft by the bulkhead in a rotatable manner; fitting the rotor on an outer circumference of the input shaft using the input shaft as a guide member; and holding one of axial ends of the rotor by the bulkhead in a rotatable manner.

According to the above-explained assembling method of the invention, a connection member is inserted into a clearance between the outer circumference of the input shaft and an inner circumference of the rotor, and the input shaft and the rotor are connected through the connection member.

Further, according to the power transmission unit of the invention, the connection member includes an output shaft of a continuously variable transmission unit assembled in advance, and according to the assembling method of the invention, both ends of the rotor are held by the bulkhead and another bulkhead in a rotatable manner, and thereafter the leading end of the output shaft is inserted into said another bulkhead to insert the connection member into a clearance between the input shaft and the rotor, and to spline the connection member to the outer circumferential face of the input shaft and to the inner circumferential face of the rotor.

According to the invention, a position of the rotor can be fixed relatively with respect to the stator using a portion of the member constituting the transmission mechanism, and the rotor can be inserted into the stator concentrically therewith while keeping the fixed position by the guide portion. Therefore, according to the invention, it is not necessary to employ a separated guide member for inserting the rotor. For this reason, the rotor can be inserted easily.

In addition to the above-explained advantage, according to the invention, the transmission mechanism side of the chamber housing the electric motor is closed by the bulkhead but the guide portion protrudes from the transmission side. For this reason, the rotor can be held at both sides utilizing the protruding portion. This facilitates insertion of the rotor into the stator even if the rotor has a permanent magnet.

In addition to the above-explained advantage, according to the invention, the protruding portion penetrates the bulkhead and the protruding portion is held by the bulkhead. For this reason, a moment acts on the protruding portion when inserting the rotor is minimized.

In addition to the above-explained advantage, according to the invention, the rotor is guided by the portion of the protruding portion of the transmission side when the rotor is fitted onto the protruding portion to some extent from the leading end of the protruding portion. For this reason, the rotor can be kept substantially concentrically with the stator when inserted into the stator.

In addition to the above-explained advantage, according to the invention, the rotor is not fitted directly onto the shaft protruding from the bulkhead but the shaft functions as the guide portion. For this reason, the rotor can be inserted into the stator easily. Especially, even if the rotor has a permanent magnet, the rotor can be inserted into the stator while avoiding adhesion of the rotor to the stator, by setting a clearance between the inner circumferential face of the rotor and the outer circumferential face of the shaft narrower than that between the outer circumferential face of the rotor and the inner circumferential face of the stator.

In addition to the above-explained advantage, according to the invention, the bulkhead is fixed to the casing through the spigot joint portion. For this reason, an accuracy of a centering of the bulkhead can be improved.

In addition to the above-explained advantage, according to the invention, the hydraulic control unit is provided underneath the transmission mechanism. For this reason, the length of the oil passage for feeding the oil to the transmission mechanism and discharging the oil therefrom can be shortened so that the arrangement of the oil passage can be simplified.

In addition to the above-explained advantage, according to the invention, the space underneath the electric motor and the transmission mechanism can be utilized to arrange the oil pan. For this reason, length of the oil passages connected to the electric motor and the transmission mechanism can be shortened so that the arrangement of the oil passages can be simplified.

According to the invention, the rotor is held by the casing or the member integral with the casing in a rotatable manner, however, the rotor is held by the aforementioned protruding portion or the shaft in the process of assembling. For this reason, the rotor can be kept concentrically with the stator when inserted into the stator, and this facilitates the insertion of the rotor into the stator.

In addition to the above-explained advantage, according to the invention, the rotor is held rotatably at its both ends by the casing or the member integral with the casing.

In addition to the above-explained advantage, according to the invention, the oil passage can be formed utilizing the bulkhead. For this reason, the unit can be downsized entirely.

In addition to the above-explained advantage, the present invention can be applied to a hybrid drive unit comprising an internal combustion engine and an electric motor or a generator so as to facilitate an assembling of the electric motor.

In addition to the above-explained advantage, according to the invention, the shaft functioning as the guide portion and the rotor are not connected directly with each other but connected through a portion of the output member. That is, the electric motor and the transmission mechanism are isolated from each other and therefore the torque cannot be transmitted therebetween even after fitting the rotor onto the shaft, until the output member is inserted between the rotor and the shaft. For this reason, the electric motor can be rotated independently until inserting the output member between the rotor and the shaft.

In addition to the above-explained advantage, the present invention facilitates an assembling work of the electric motor in a power transmission unit comprising a transmission mechanism such as a geared transmission, a belt type continuously variable transmission and a toroidal type continuously variable transmission.

In addition to above, according to the invention, the transmission mechanism can be assembled by inserting the elements sequentially from one of the open end sides of the casing. The chamber of the transmission side is then closed by the bulkhead but the input shaft protrudes towards said one of the open end sides of the casing. Therefore, the rotor can be inserted into the casing to be assembled using the protruding input shaft as the guide member. That is, all of the transmission mechanism and the electric motor can be entered into the casing from one of the open end side of the casing. Therefore, it is not necessary to turn the casing so that the power transmission unit can be assembled easily.

In addition to above, according to the invention, the rotor is not connected with the input shaft before inserting the connection member. Therefore, the rotor can be rotated independently to be inspected and adjusted.

In addition to above, according to the invention, the output shaft of the continuously variable transmission unit is splined to the rotor and the input shaft as a result of assembling the continuously variable transmission unit. Consequently, the rotor and the input shaft are connected with each other and splined to the output shaft.

### BRIEF DESCRIPTION OF THE DRAWINGS

FIG. 1 is a cross-sectional view showing one example of the invention.

FIG. 2 is a skeleton diagram schematically showing a drive line of a hybrid vehicle comprising a power transmission unit to which the invention is applied.

FIG. 3 is a table showing a relation between gear stages and engagement states of the mechanical transmission.

FIG. 4 is a nomographic diagram explaining operating states of the planetary gear mechanisms.

FIG. 5 is a diagram schematically showing one example of a speed change diagram of the mechanical transmission.

FIG. 6 is a diagram showing one example of an arrangement of a shift position of a shifting device.

FIG. 7 is a diagram showing an example of input signals and output signals of an electronic control unit.

### BEST MODE FOR CARRYING OUT THE INVENTION

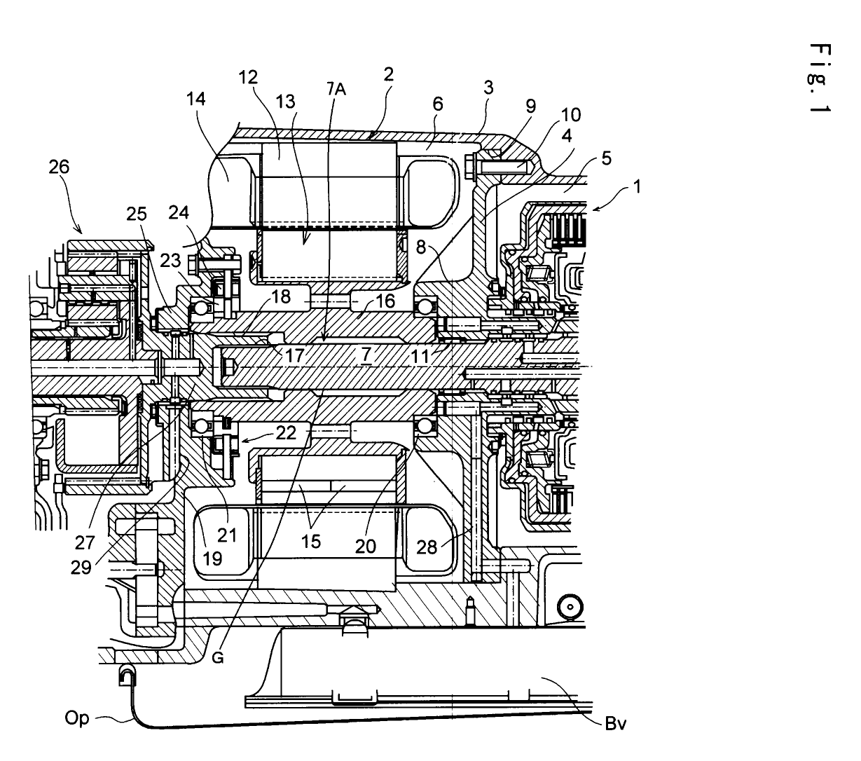

Next, this invention will be explained in connection with its specific example. FIG. 1 is a cross-sectional view partially showing a power transmission unit to which the invention is applied. As illustrated in FIG. 1, the power transmission unit comprises a mechanical transmission unit 1 and an electric motor 2. Those transmission unit 1 and electric motor 2 are housed in a casing 3. One of the open ends of the casing 3 (i.e., left side of FIG. 1) opens widely, and an open end of other side (i.e., right side of FIG. 1) opens narrowly to allow passage of a not shown output shaft therethrough. An internal space of the casing 3 is divided into two chambers 5 and 6 by a bulkhead 4 built inside of the casing 3. As shown in FIG. 1, the transmission unit 1 is housed in the right chamber 5, and the electric motor 2 is arranged adjacent to the bulkhead 4 in the left chamber 6.

A geared transmission mechanism, or a belt-type or toroidal type continuously variable transmission mechanism can be used as the transmission unit 1. That is, the transmission unit 1 is adapted to vary a speed change ratio by changing a power transmission route. Here will be explained an example of the geared transmission unit 1 composed mainly of a planetary gear mechanism. The transmission unit 1 comprises an input shaft 7 penetrating the bulkhead 4 to protrude toward the chamber 6 housing the electric motor 2. The bulkhead 4 is a plate-like member comprising a boss portion 8 on its center side. The bulkhead 4 is engaged with a spigot joint portion 9 formed on an inner circumference of the casing 3 to be centered, and fixed with the casing 3 by a bolt 10. The input shaft 7 penetrates the bulkhead 4 along a center axis of the boss portion 8 of the bulkhead 4, and the input shaft 7 is held by the bulkhead 4 in a rotatable manner through a bearing 11 fitted onto an outer circumference of the input shaft 7.

On the other hand, the electric motor 2 comprises a stator (i.e., a stationary part) 12 and a rotor (i.e., a rotary part) 13 arranged in an inner circumferential side of the stator 12 and concentrically with the stator 12. An appropriate type of an electric motor, e.g., a permanent magnet synchronous motor can be used as the electric motor 2. In this case, the stator 12 is provided with a coil 14, and the rotor 13 is provided with a permanent magnet 15. The rotor 13 comprises a cylindrical portion 16 on its inner circumferential side. A length of the cylindrical portion 16 is comparable to an axial length of the coil 14. The input shaft 7 protrudes from the end portion of the rotor 13 of the bulkhead 4 side to the other end of the rotor 13. On an outer circumferential face of a leading end of the input shaft 7, there is formed a spline 17. The aforementioned cylindrical portion 16 of the rotor 13 is fitted loosely onto the outer circumference of the input shaft 7 between the spline 17 and a base end of the input shaft 7. An inner diameter of a portion of the cylindrical portion 16 facing to the spline 17 of the input shaft 7 is larger than an outer diameter of the spline 17. That is, a spline 18 is formed on the inner circumferential face of the cylindrical portion 16 facing to the spline 17 while keeping a distance from the spline 17.

The input shaft 7, the rotor 13 and the stator 12 are arranged coaxially. A (minimum) clearance between the outer circumferential face of the input shaft 7 and the inner circumferential face of the rotor 13 (or the cylindrical portion 16) is smaller than a (minimum) clearance between the outer circumferential face of the rotor 13 and the inner circumferential face of the stator 12. For this reason, the outer circumferential face of the rotor 13 will not be contacted with the inner circumferential face of the stator 12 even if the rotor 13 is misaligned in a radial direction and contacted with the outer circumferential face of the input shaft 7 when assembled. In other words, even if the rotor 13 is fitted loosely onto the outer circumferential face of the input shaft 7 using the outer circumferential face of the input shaft 7 as a guide portion, the rotor 13 will not be contacted with the stator 12. That is, the outer circumferential face of the protruding portion 7A of the input shaft 7, specifically, the portion of the protruding portion 7A between the spline 17 and the base end thereof functions as a guide portion G when sliding the rotor 13 in the axial direction.

The chamber 6 accommodating the electric motor 2 therein is defined by another bulkhead 19 attached to the inner circumference of the casing 3 and opposed to the bulkhead 4. The rotor 13 is held by the bulkheads 4 and 19 in a rotatable manner through bearings 20 and 21 fitted onto both ends of the cylindrical portion 16. As explained above, the rotor 13 is fitted loosely onto the input shaft 7 and the splines 17 and 18 are not splined to each other, therefore, the rotor 13 can be rotated independently when the rotor 13 is fitted onto the input shaft 7 and held by the bearings 20 and 21.

A rotor 23 of a resolver 22 is fitted onto an end portion of the cylindrical portion 16 of another bulkhead 19 side. Also, a stator 24 is arranged around an outer circumference of the rotor 23 to be opposed to the rotor 23 in the radial direction. The stator 24 is fixed to an inner face of aforementioned another bulkhead 19.

In the aforementioned another bulkhead 19, there is formed a boss portion 25 coaxially with the center axis of the input shaft 7. An output shaft 27 of a power distribution mechanism 26 is inserted into the boss portion 25. The output shaft 27 transmits a power from the power distribution mechanism 26 to the electric motor 2 and to the transmission unit 1. A leading end of the output shaft 27 is formed cylindrically so that the cylindrical leading end can be inserted into an inner circumferential side of the cylindrical portion 16 and fitted onto an outer circumference of the input shaft 7. Spilnes are formed on both inner and outer face of the cylindrical leading end of the output shaft 27 so that the cylindrical leading end is splined to both the spline 18 of the rotor 13 and the spline 17 of the input shaft 7. That is, the rotor 13 and the input shaft 7 are indirectly connected with each other in a power transmittable manner through the output shaft 27 corresponding to the connection member of the invention. Here, the power distribution mechanism 26 will be explained later.

Oil passages 28 and 29 are formed to penetrate the bulkheads 4 and 19. The oil passages 28 and 29 are adapted to feed lubricating oil or oil pressure to the transmission unit 1, the power distribution mechanism 26, and the bearings 11, 20 and 21, and to discharge the lubricating oil or oil pressure from those elements. In order to feed and discharge oil pressure through the oil passages 28 and 29, a hydraulic control circuit Bv functioning as a hydraulic control unit is arranged underneath the casing 3. More specifically, the aforementioned transmission unit 1 and electric motor 2 are housed in the integrally structured casing 3, and the hydraulic control circuit Bv is arranged underneath the casing 3 at a portion corresponding to the positions of the transmission unit 1 and the electric motor 2. The hydraulic control circuit Bv comprises not shown various kinds of electrically controlled valves and a valve controlled by pilot pressure, and the oil passages 28 and 29 are communicated with the hydraulic control circuit Bv. Additionally, the hydraulic control circuit Bv is covered by an oil pan Op attached to a lower face of the casing 3. The oil pan Op is commonly used to reserve the oil fed and discharged to/from the transmission unit 1, the electric motor 2 and the power distribution mechanism 26 of the continuously variable transmission unit. Thus, the hydraulic control circuit Bv is housed in the oil pan Op.

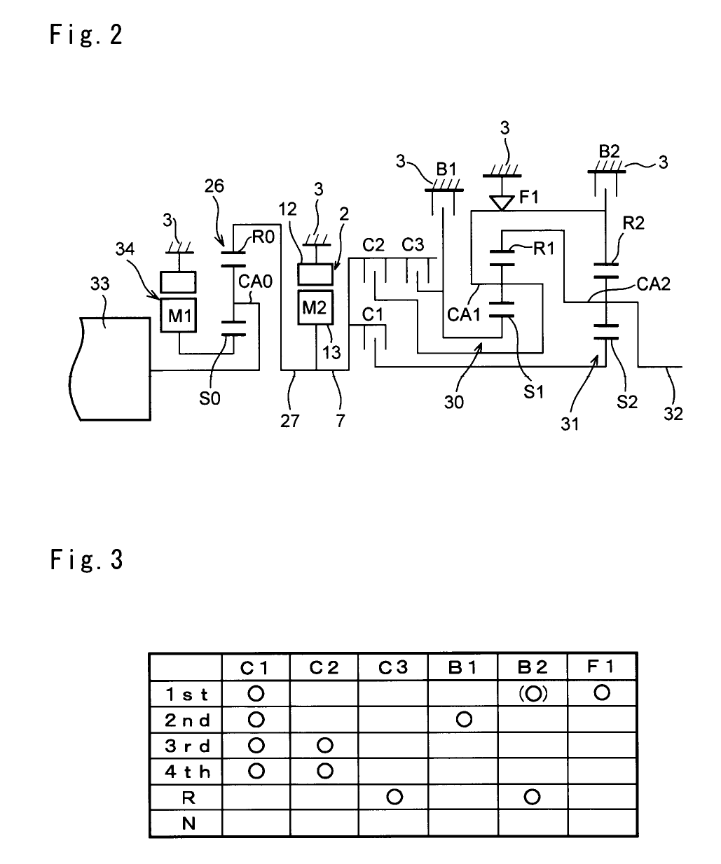

The power transmission unit shown in FIG. 1 can be mounted on a hybrid vehicle, and example thereof is illustrated in FIG. 2. FIG. 2 shows an example of so-called a “2 motors hybrid drive unit” arranged in an anteroposterior direction of the vehicle. A configuration of the transmission unit 1 is explained first of all. According to the example shown in FIG. 2, the transmission unit 1 is capable of setting four kinds of speed change ratios of forward direction and one speed change ratio of reverse direction using two sets of planetary gear mechanisms 30 and 31. The planetary gear mechanisms 30 and 31 may be single pinion type but also be double pinion type. In the example shown in FIG. 2, however, single pinion type planetary gear mechanisms are employed. Specifically, the planetary gear mechanisms 30 and 31 perform a differential action using rotary elements such as sun gears S1 and S2 as external gears, ring gears R1 and R2 as internal gears arranged concentrically around the sun gears S1 and S2, and carriers CA1 and CA2 holding pinion gears arranged between the sun gears S1 and S2 and the ring gears R1 and R2 and meshing with the sun gear and the ring gear.

The carrier CA1 of the first planetary gear mechanism 30 and the ring gear R2 of the second planetary gear mechanism 31 are connected with each other, and the ring gear R1 of the first planetary gear mechanism 30 and the carrier CA2 of the second planetary gear mechanism 31 are connected with each other. That is, the planetary gear mechanisms 30 and 31 function as a so-called “CR-CR coupled type complex planetary gear mechanism”.

In order to transmit a power selectively to the complex planetary gear mechanism, there are provided three clutch mechanisms C1, C2 and C3. For example, those clutch mechanisms C1, C2 and C3 are hydraulic frictional engagement devices. The first clutch mechanism C1 is arranged between the input shaft 7 and the sun gear S2 of the second planetary gear mechanism 31. The second clutch mechanism C2 is arranged between the carrier CA1 of the first planetary gear mechanism 30 and the input shaft 7. The third clutch mechanism C3 is arranged between the sun gear S1 of the first planetary gear mechanism 30 and the input shaft 7.

In addition, there are provided a first brake mechanism B1 for selectively fixing the sun gear S1 of the first planetary gear mechanism 30, and a second brake mechanism B2 for selectively fixing the ring gear R2 of the second planetary gear mechanism 31. A hydraulic multi-disc brake or a band brake can be used as the brake mechanisms B1 and B2. Also, a one-way clutch F1 is arranged in parallel with the second brake mechanism B2. The one-way clutch F1 is adapted to be engaged to halt an integral rotation of the carrier CA1 of the first planetary gear mechanism 30 and the ring gear R2 of the second planetary gear mechanism 31 in the direction opposite to the rotational direction of the input shaft 7. Further, an output shaft 32 is connected with the carrier CA2 of the second planetary gear mechanism 31. The output shaft 32 is arranged coaxially with the aforementioned input shaft 7, and protrudes from the casing 3.

Next, here will be explained the power distribution mechanism 26. The power distribution mechanism 26 is a mechanism comprising a planetary gear mechanism, and distributing a power outputted from an internal combustion engine 33 to a motor generator (M1) 34 and to the transmission unit 1. Both single and double pinion type planetary gear mechanisms capable of performing a differential action using three rotary elements may be used. In the example shown in FIG. 2, a single pinion type planetary gear mechanism is employed. The planetary gear mechanism is adapted to function as a speed increasing mechanism. Specifically, the internal combustion engine 33 is connected with a carrier CA0, the motor generator 34 is connected with a sun gear S0, and the output shaft 27 is connected with a ring gear R0.

The output shaft 27 of the power distribution mechanism 26 is also connected with the input shaft 7 of the transmission unit 1, and the rotor 13 of the aforementioned electric motor (M2) 2 is connected with those output shaft 27 and input shaft 7. Here, the motor generator 34 may also be a generator, and the electric motor 2 may also be a motor generator having a generating function. The motor generator 34 and the electric motor 2 are connected with a battery through a controller such as a (not shown) inverter. A drive torque, a generation torque, a generation amount and so on of the motor generator 34 and the electric motor 2 are controlled by controlling the inverter by an electronic control unit.

As shown in FIG. 3, the transmission unit 1 composed mainly of the aforementioned two sets of the planetary gear mechanisms 30 and 31 is capable of setting four forward stages and one reverse stage by engaging and releasing the clutch mechanisms C1, C2 and C3, the brake mechanisms B1 and B2, and one-way clutch F1. FIG. 3 is a table indicating an engagement of the aforementioned elements, i.e., clutch and brake mechanisms. Here, in FIG. 3, “◯” represents an “engagement” of the element, a blank means that the element is released, and “(◯)” represents that the element is engaged to apply power source braking (or engine braking). The clutch mechanisms C1, C2 and C3, the brake mechanisms B1 and B2 are controlled to be engaged and released by an oil pressure outputted from the hydraulic control unit.

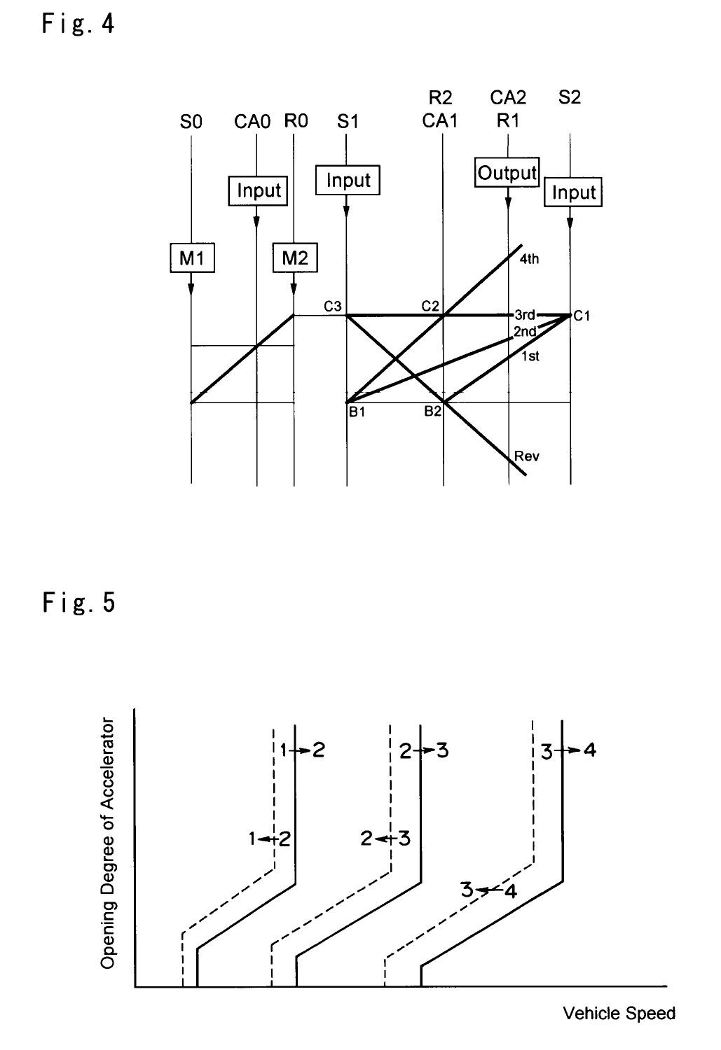

A nomographic diagram of the power distribution mechanism 26 and a nomographic diagram of the transmission unit 1 are shown in FIG. 4. In the nomographic diagram, longitudinal axes representing the rotary elements of the planetary gear mechanism are arranged in parallel at intervals based on a gear ratio (i.e., a ratio between teeth numbers of the ring gear and the sun gear) of the planetary gear mechanism. A base line perpendicular to the longitudinal axes represents a rotational speed of zero, and the rotational speed above the base lines on the longitudinal axis is a rotational speed in the forward direction. As explained, the single type planetary gear mechanisms are used in the example of FIG. 2. Therefore, provided that the clearance between the longitudinal axes representing the sun gear and the carrier is set to “1”, the clearance between the longitudinal axes representing the carrier and the ring gear indicates the gear ratio. In FIG. 4, the reference numerals in common with those used in FIG. 2 are respectively allotted to the longitudinal axes representing the rotary elements. Also, the rotational speeds of the rotary elements represented by the longitudinal axes of the cases in which the clutch mechanisms C1, C2 and C3, the brake mechanisms B1 and B2, and the one-way clutch F1 are engaged are specified using the reference numerals in common with those used in FIG. 2. Further, those points on the longitudinal axes indicating the rotational speeds of the rotary elements under the predetermined operating state are connected by bold lines. That is, the bold lines indicate operating states of the planetary gear mechanisms.

As can be seen from the nomographic diagram of the power distribution mechanism 26 in the left side of FIG. 4, a rotational speed of the carrier CA0 functioning as an input element connected with the internal combustion engine 33 is fluctuated by varying a rotational speed of the motor generator 34 while keeping a rotational speed of the ring gear R0 functioning as an output element at a constant speed. In this situation, the motor generator 34 functions as a generator when the rotational speed thereof is controlled to be lowered. The generated electric power is supplied to the electric motor 2 to operate the electric motor 2 as an electric motor, or otherwise stored in a battery. The rotational speed of the internal combustion engine 33 thus can be varied continuously by the motor generator 34 so that the power distribution mechanism 26 functions as a continuously variable transmission. More specifically, the power distribution mechanism 26 functions as a continuously variable transmission as a result of controlling the motor generator 34 electrically, that is, the power distribution mechanism 26 functions as an electrical continuously variable transmission.

A speed change operation of the transmission unit 1 can be carried out in accordance with a running condition of the vehicle, for example, a gear stage thereof can be set in accordance with an output torque demand or corresponding opening degree of an accelerator and a vehicle speed. For example, the gear stage is determined on the basis of a map of gear stages prepared in advance using an output torque and a vehicle speed as parameters, and a speed change is carried out to achieve the determined gear stage. One example of the map is shown in FIG. 5. In FIG. 5, solid lines are upshift lines, and a judgment of an upshifting is satisfied when a running condition of the vehicle is changed to across the upshift line from a low speed side to a high speed side or from a high torque side to a low torque side. On the other hand, in FIG. 5, broken lines are downshift lines, and a judgment of a downshifting is satisfied when the running condition of the vehicle is changed to across the downshift line from the high speed side to the low speed side or from the low torque side to the high torque side.

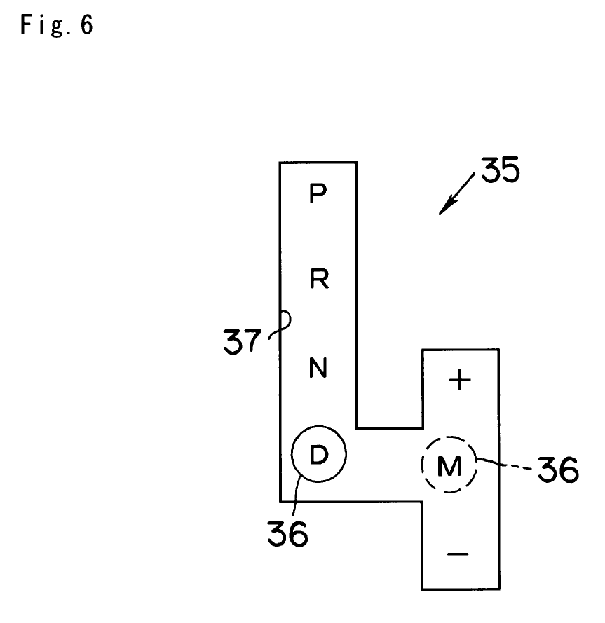

All of those gear stages can be established in case a Drive range (or a drive position) is selected, however, the gear stages of the high speed side are restricted under a manual shifting mode (i.e., manual mode). FIG. 6 illustrates an arrangement of shift positions in a shifting device 35 for outputting a shift position signal. In the shifting device 35, a Parking (P) for keeping the vehicle being stopped, a Reverse (R), a Neutral (N) and a Drive (D) positions are arranged linearly in an anteroposterior direction of the vehicle. A Manual position (M) is arranged adjacent to the Drive position (D) in the width direction of the vehicle, and an upshift position (+) and a downshift position (−) are arranged above and below the manual position. Those shift positions are connected through a guide groove 37 guiding a shift lever 36. Therefore, the shift position is selected arbitrary by moving the shift lever 36 along the guide groove 37, and the shift position signal of selected position is consequently outputted.

In case the Drive position is selected, all of the forward stages of the transmission unit 1 from the first to fourth stages can be set depending on a running condition. On the other hand, in case the shift lever 36 is moved from the Drive position to the Manual position, the Drive position is maintained and a shifting can be selected up to the fourth stage. However, in this case, a downshift signal (i.e., a down range signal) is outputted each time the shift lever 36 is moved to the downshift position. As a result, the gear stage or a gear range is shifted sequentially to a lower stage. To the contrary, an upshift signal is outputted each time the shift lever 36 is moved to the upshift position, so that the gear stage or gear range is shifted sequentially to the higher stage.

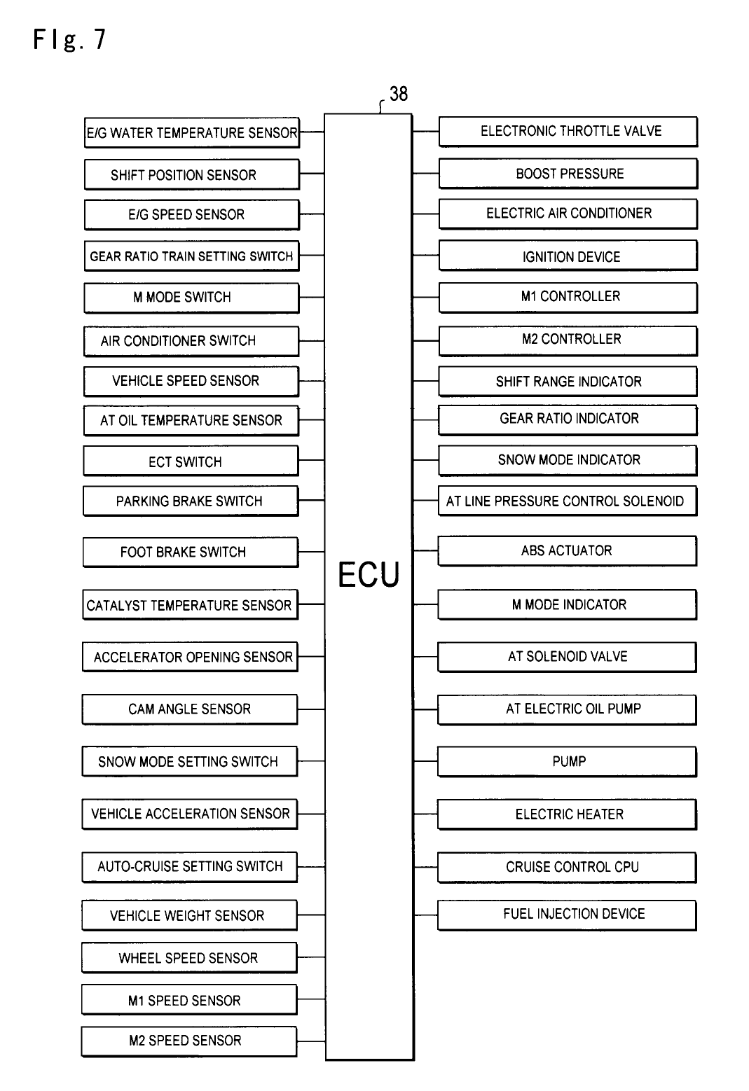

In order to control the power transmission unit entirely by controlling the aforementioned controllers and the hydraulic control unit by an electric signal, there is provided an electronic control unit (ECU) 38. The signals inputted to the electronic control unit 38, and the signals outputted form the electronic control unit 38 are indicated in FIG. 7. The electronic control unit 38 comprises a microcomputer composed mainly of CPU, ROM, RAM and an input/output interface and so on. The electronic control unit 38 carries out drive controls, e.g., a hybrid drive control of the internal combustion engine 33, the electric motor 2 and the motor generator 34, and a shift control of the transmission unit 1, by carrying out a signal process in accordance with a program stored in ROM in advance while utilizing a temporal storage function of RAM.

As shown in FIG. 7, a signal indicating a water temperature of the engine, a signal indicating a shift position, a signal indicating the rotational speed Ne of the internal combustion engine 33, a signal indicating the gear ratio train setting value, a signal instructing M mode (i.e., a motor running mode), a signal indicating an operation of an air-conditioner, a signal indicating a vehicle speed corresponding to the rotational speed NOUT of the output shaft 32, a signal indicating an oil temperature of an operating oil (i.e., an AT oil temperature) of the transmission unit 1, a signal indicating an operation of a parking brake, a signal indicating an operation of a foot brake, a signal indicating a temperature of a catalyst, an accelerator opening signal indicating a stepping amount of the accelerator corresponding to an output demand of the driver, a cam angle signal, a signal indicating a snow mode setting, an acceleration signal indicating a longitudinal acceleration of the vehicle, a signal indicating an auto-cruise running, a signal indicating a weight of the vehicle, a signal indicating a speed of individual wheels, a signal indicating a rotational speed of the motor generator (M1) 34, a signal indicating a rotational speed of the electric motor (M2) 2 and so on, are inputted to the electronic control unit 40.

On the other hand, a driving signal to a throttle actuator for controlling an opening degree of an electronic throttle valve, a fuel feeding signal for controlling a feeding amount of the fuel from a fuel injection device to the internal combustion engine 33, a boost regulating signal for regulating a boost pressure, a signal for activating the electric air-conditioner, an ignition signal for commanding a timing to ignite the internal combustion engine 33 by an ignition device, a command signal for commanding the controllers to activate the motor generator (M1) 34 and the electric motor (M2) 2, a shift position (or an operating position) indicating signal for activating a shift indicator, a signal indicating a gear ratio, a signal indicating a snow mode, a signal for activating an ABS actuator for preventing a slippage of the wheel at a braking time, an M mode indication signal indicating that M mode is selected, a valve command signal for activating a solenoid valve of the hydraulic control unit to control the hydraulic actuator of the hydraulic frictional engagement devices of the transmission unit 1, a drive command signal for activating an electric hydraulic pump as a hydraulic source of the hydraulic control unit, a signal for activating an electric heater, a signal to a cruise control computer and so on, are outputted from the electronic control unit 38.

Next, here will be explained a procedure (or method) of assembling the aforementioned power transmission unit. First of all, before fixing the bulkheads 4 and 19 to the casing 3, the components of the transmission unit 1 are inserted into the casing 3 sequentially from the wider opening (of the side where the internal combustion engine 33 is to be placed after a completion of assembling), and the inserted components are assembled in the casing 3. Then, the bulkhead 4 is engaged with the spigot joint portion 9 formed on an inner circumference of the casing 3 while inserting the input shaft 7 of the transmission 1 into the boss portion 8 of the bulkhead 4, and fixed with the casing 3 by a bolt 10. The chamber 5 housing the transmission unit 5 is thus closed, and the input shaft 7 is held by the boss portion 8 through the bearing 11 in a rotatable manner.

After that, the stator 12 of the electric motor 2 is inserted into the inner circumference of the casing 3. In this situation, the input shaft 7 protrudes coaxially with the stator 12. The cylindrical portion 16 of the rotor 13 is fitted onto the protruding portion 7A of the input shaft 7, and the rotor 13 is inserted along the axial direction of the input shaft 7. That is, the input shaft 7 functions as a guide portion G so that the stator 13 can be inserted along the axial direction without contacting with the inner circumferential face of the stator 12. In this case, the bearing 20 is fitted into the boss portion 8 of the bulkhead 4 in advance, or fitted onto an outer circumference of the end portion of the cylindrical portion 16 of the rotor 13 in advance. Therefore, one of the end portions of the cylindrical portion 16 is held by the bulkhead 4 through the bearing 20 in a rotatable manner.

After thus inserting the rotor 13 into the inner circumference of the stator 12, another bulkhead 19 is inserted into the casing 3 and fixed to the inner circumferential face of the casing 3. In this case, the rotor 23 of the resolver 22 is fitted onto the cylindrical portion 16, and the stator 24 of the resolver 22 is fixed to the inner face of another bulkhead 19 in advance. Also, the bearing 21 is fitted onto the outer circumferential face of other end of the cylindrical portion 16 or fitted into an inner circumferential portion of another bulkhead 19 in advance. Therefore, the other end of the cylindrical portion 16 is held by the aforementioned another bulkhead 19 through the bearing 21 in a rotatable manner. That is, the rotor 13 is held by the bulkheads 4 and 19 through the bearings 20 and 21 in a rotatable manner. In this situation, the rotor 13 and the input shaft 7 are not connected with each other and the rotor 13 is allowed to rotate around the input shaft 7. That is, it is possible to rotate the rotor 13 independently. For this reason, the electric motor can be driven separately from the transmission unit 1 to be examined.

Then, the output shaft 27 of the power distribution mechanism 26 assembled in advance is inserted into the inner circumferential side of the cylindrical portion 16 through the aforementioned another bulkhead 19. As explained above, the leading end of the output shaft 27 is formed into a cylindrical shaft, and a spline is formed on both inner and outer circumferential faces thereof. Therefore, the leading end of the output shaft 27 is splined to the spline 17 of the input shaft 7 and to the spline 18 of the rotor 13. As a result, the output shaft 27, the input shaft 7 and the rotor 13 are connected in a torque transmittable manner.

Thus, according to the invention shown in FIG. 1, the rotor 13 is fitted onto the input shaft 7, and the rotor 13 is inserted into the inner circumference of the stator 12 using the input shaft 7 as the guide portion G. That is, both ends of the rotor 13 are substantially held when it is inserted. For this reason, the rotor 13 will not adhere nor contact to the stator 12 even if the stator 12 has a permanent magnet. Moreover, the rotor 13 and the input shaft 7 are not yet connected with each other when the rotor 13 is inserted into the inner circumference of the stator 12. Therefore, the electric motor 2 can be rotated independently to be examined. Thus, an operation test of the electric motor 2 can be carried out easily and accurately.

Here, in the example thus far explained, the present invention is applied to the power transmission unit of a hybrid drive unit. However, the present invention should not be limited to the aforementioned example. This means that the present invention may also be applied to other kinds of power transmission units such as a power transmission unit in an electric vehicle. On the other hand, the transmission mechanism used in the present invention should not be limited to the aforementioned planetary gear type geared transmission mechanism but a transmission mechanism without speed changing function may also be used. According to the invention, the electric motor also should not be limited to the permanent magnetic type electric motor but other kinds of appropriate electric motor may also be used. Further, the connection member used in the present invention should not be limited to the output shaft 27 of the power distribution mechanism 26 but other kinds of appropriate member may also be used as the connection member. Additionally, the means for transmitting torque should not be limited to the spline but may also be an engaging means for integrating members in a rotational direction such as a serration and a slide key.

1. A power transmission unit comprising:
an electric motor having a rotor arranged in an inner circumference of a stator and concentrically with the stator, and
a transmission mechanism for transmitting power, wherein:
a portion of a predetermined constructional element of the transmission mechanism protrudes toward the stator or rotor side, and the protruding portion functions as a guide portion for inserting the rotor into the stator concentrically.

2. The power transmission unit as claimed in claim 1, wherein:
the electric motor and the transmission mechanism are housed in a casing;
a bulkhead integral with the casing is disposed between the electric motor and the transmission mechanism;
the transmission mechanism is housed in a chamber defined by the bulkhead; and
the electric motor is disposed adjacent to the bulkhead in a chamber opposite to the chamber housing the transmission mechanism.

3. The power transmission unit as claimed in claim 2, wherein:
the protruding portion functioning as the guide portion protrudes toward the electric motor side while penetrating the bulkhead, and supported by the bulkhead.

4. The power transmission unit as claimed in claim 1, wherein:
a portion of the protruding portion closer to the transmission mechanism side than a leading end side thereof functions as the guide portion.

5. The power transmission unit as claimed in claim 1, wherein:
the protruding portion functioning as the guide portion includes a shaft for transmitting a power to the transmission mechanism;
the shaft is inserted into the rotor and allowed to rotate relatively therewith; and
a connection member is interposed between the shaft and the rotor to connect the shaft and the rotor in a power transmittable manner.

6. The power transmission unit as claimed in claim 2, wherein:
the bulkhead interlocks with the casing at a spigot joint portion.

7. The power transmission unit as claimed in claim 1, wherein:
a hydraulic control unit is provided underneath the transmission mechanism.

8. The power transmission unit as claimed in claim 1, wherein:
an oil pan for reserving oil used commonly in the electric motor and the transmission mechanism is provided underneath the electric motor and the transmission mechanism.

9. The power transmission unit as claimed in claim 1, wherein:
the rotor is held in a rotatable manner by the casing housing the electric motor and the transmission mechanism or by a member integral with the casing.

10. The power transmission unit as claimed in claim 2, wherein:
the casing or the member integral with the casing includes the bulkhead and an another bulkhead opposed to the bulkhead.

11. The power transmission unit as claimed in claim 10, comprising:
an oil passage passing through at least one of the bulkhead or another bulkhead.

12. The power transmission unit as claimed in claim 1:
wherein an electrical drive unit functioning as an electric motor or a generator and an internal combustion engine are connected with a differential mechanism; and
further comprising an electrical transmission varying a speed of the internal combustion engine continuously in accordance with a speed of the electrical drive unit.

13. The power transmission unit as claimed in claim 12, wherein:
the differential mechanism comprises a planetary gear mechanism.

14. The power transmission unit as claimed in claim 12, wherein:
the differential mechanism functions as a speed increasing mechanism an output speed thereof is higher than that of the internal combustion engine.

15. The power transmission unit as claimed in claim 12, wherein:
a portion of an output member of the differential mechanism or a member integral with the output member is connected with the shaft and the rotor.

16. The power transmission unit as claimed in claim 15, wherein:
the portion of the output member or the member integral with the output member is splined to at least any of the shaft and the rotor.

17. The power transmission unit as claimed in claim 1, wherein:
the transmission mechanism includes a mechanical transmission changing a speed change ratio thereof by changing a power transmission route by a mechanical means.

18. The power transmission unit as claimed in claim 17, wherein:
the mechanical transmission includes a planetary gear mechanism.

19. The power transmission unit as claimed in claim 17, wherein:
the mechanical transmission includes a mechanism setting a reverse stage.

20. An assembling method of a power transmission unit, in which an electric motor having a rotor arranged in an inner circumference of a stator and concentrically with the stator and a transmission mechanism transmitting power are housed in a casing, comprising:
assembling the transmission mechanism by inserting elements of the transmission mechanism into the casing from one of the open ends of the casing to assemble those elements;
thereafter fixing a bulkhead in the casing to define a chamber for housing the transmission mechanism;
inserting an input shaft of the transmission mechanism into the bulkhead and holding the input shaft by the bulkhead in a rotatable manner;
fitting the rotor on an outer circumference of the input shaft using the input shaft as a guide member; and
holding one of the axial ends of the rotor by the bulkhead in a rotatable manner.

21. The assembling method of a power transmission unit as claimed in claim 20, further comprising:
inserting a connection member into a clearance between the outer circumference of the input shaft and an inner circumference of the rotor to connect the input shaft and the rotor through the connection member.

22. The assembling method of a power transmission unit as claimed in claim 21:
wherein the connection member includes an output shaft of a continuously variable transmission unit assembled in advance; and
further comprising holding both ends of the rotor by the bulkhead and another bulkhead in a rotatable manner; and
thereafter letting the leading end of the output shaft through said another bulkhead to insert the connection member into a clearance between the input shaft and the rotor, and to spline the connection member to the outer circumferential face of the input shaft and to the inner circumferential face of the rotor.
